(19) United States
(12) Patent Application Publication
(10) Pub. No.: US 2026/0114296 A1
(43) Pub. Date: Apr. 23, 2026

(54) SEMICONDUCTOR PACKAGE HAVING COPPER PLATED SOURCE PADS AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Long-Ching Wang, Cupertino, CA (US); Lingpeng Guan, San Jose, CA (US); Jun Lu, San Jose, CA (US); Madhur Bobde, Sunnyvale, CA (US)

(73) Assignee: ALPHA AND OMEGA SEMICONDUCTOR INTERNATIONAL LP, TORONTO, ON (CA)

(21) Appl. No.: 18/924,929

(22) Filed: Oct. 23, 2024

(51) Int. Cl. H01L 23/495; H01L 23/31; H01L 23/528

(52) U.S. Cl. CPC H10W 70/481; H10W 20/427; H10W 70/457; H10W 74/114

(57) ABSTRACT

A semiconductor package comprises a lead frame, an FET, a copper layer, a source metal clip, and a molding encapsulation. The FET comprises a gate bus line, a gate electrode, and a source electrode on a top surface of the FET and a drain electrode on a bottom surface of the FET. A method comprises the steps of providing a wafer; attaching a seed layer; applying a photoresist layer; forming openings; electro plating of copper; removing the photoresist layer; removing the seed layer; applying a grinding process; applying a dicing process; attaching a lead frame; mounting source metal clips; forming a molding encapsulation; and applying a singulation process.

### FIELD OF THE INVENTION

This invention relates generally to a semiconductor package having copper plated sections on source pads and a method of making the semiconductor package. More particularly, the present invention relates to a semiconductor package, having a plurality of small, separated copper plated sections on the source pads.

### BACKGROUND OF THE INVENTION

Shapes and sizes of conventional electroless plated source pads of field-effect transistors (FETs) are somewhat fixed. It results in narrow areas surrounding the gate bus lines, leading to higher possibility of electrical short. Therefore, no protections are applied over the gate bus lines. The gate bus lines tend to be damaged from the pressure of the source metal clips.

The present disclosure includes a plurality of small, separated, electro, copper plated source pads. It reduces the warpage of the FET after the plating process. It also reduces the warpage of the semiconductor package after the die bonding process. A thickness of an aluminum layer on top of a wafer may be reduced from a range of 4-7 microns to 2-3 microns.

### SUMMARY OF THE INVENTION

A semiconductor package comprises a lead frame, an FET, a copper layer, a source metal clip, and a molding encapsulation. The FET comprises a gate bus line, a gate electrode, and a source electrode on a top surface of the FET and a drain electrode on a bottom surface of the FET. The molding encapsulation encloses the FET, the copper layer, the source metal clip, and a majority portion of the lead frame.

A method for fabricating a plurality of semiconductor packages is disclosed. The method comprises the steps of providing a wafer; attaching a seed layer; applying a photoresist layer; forming openings; electro plating of copper; removing the photoresist layer; removing the seed layer; applying a grinding process; applying a dicing process; attaching a lead frame; mounting source metal clips; forming a molding encapsulation; and applying a singulation process.

### BRIEF DESCRIPTION OF THE DRAWINGS

FIG. 1A shows a perspective view of a semiconductor package in examples of the present disclosure.

FIG. 1B shows a perspective view of another semiconductor package in examples of the present disclosure.

FIG. 2 shows a perspective view of an FET in examples of the present disclosure.

FIG. 3 shows a perspective view of an FET with plated copper in examples of the present disclosure.

FIG. 4 is a flowchart of a process to develop a semiconductor package in examples of the present disclosure.

FIG. 5A shows a perspective view and FIGS. 5B, 5C, 5D, 5E, 5F, 5G, 5H, 5I, 5J, 5K, 5L, 5M, and 5N show the cross sections, viewed from a direction perpendicular to the AA′ plane, of the corresponding steps of the process of FIG. 4 in examples of the present disclosure.

FIGS. 6A, 6B, and 6C show the cross sections of a portion of the corresponding steps of the process of FIG. 4, having a gate bond wire, in examples of the present disclosure.

FIG. 7A shows a perspective view and FIGS. 7B, 7C, 7D, 7E, 7F, 7G, 7H, 7I, 7J, 7K, 7L, 7M, and 7N show the cross sections, viewed from a direction perpendicular to the BB′ plane, of the corresponding steps of the process of FIG. 4 in examples of the present disclosure.

### DETAILED DESCRIPTION OF THE INVENTION

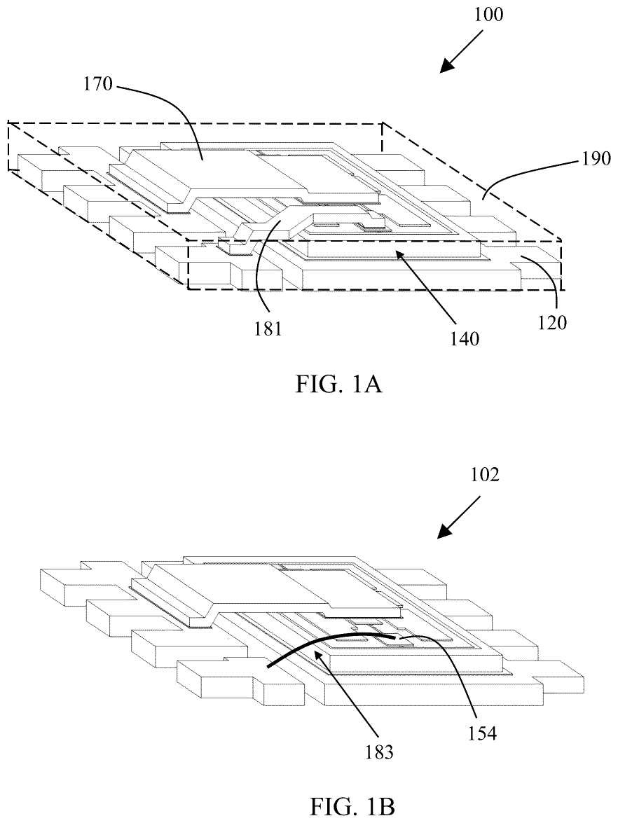

FIG. 1A shows a perspective view of a semiconductor package 100 in examples of the present disclosure. FIG. 1B shows a perspective view of another semiconductor package 102 in examples of the present disclosure. The semiconductor package 100 is similar to the semiconductor package 102. For simplicity and clarity, a molding encapsulation 190 is shown in transparent (dashed lines) in FIG. 1A and molding encapsulation is not shown in FIG. 1B. One difference between FIG. 1A and FIG. 1B is that FIG. 1A includes a gate metal clip 181 and FIG. 1B includes a bond wire 183.

In FIGS. 1A and 1B, the semiconductor package 100 comprises a lead frame 120, an FET 140, a copper layer 350 of FIG. 3, a source metal clip 170, and the molding encapsulation 190. In one example, the semiconductor package 100 is a metal oxide semiconductor field effect transistor (MOSFET). In another example, the semiconductor package 102 is a MOSFET.

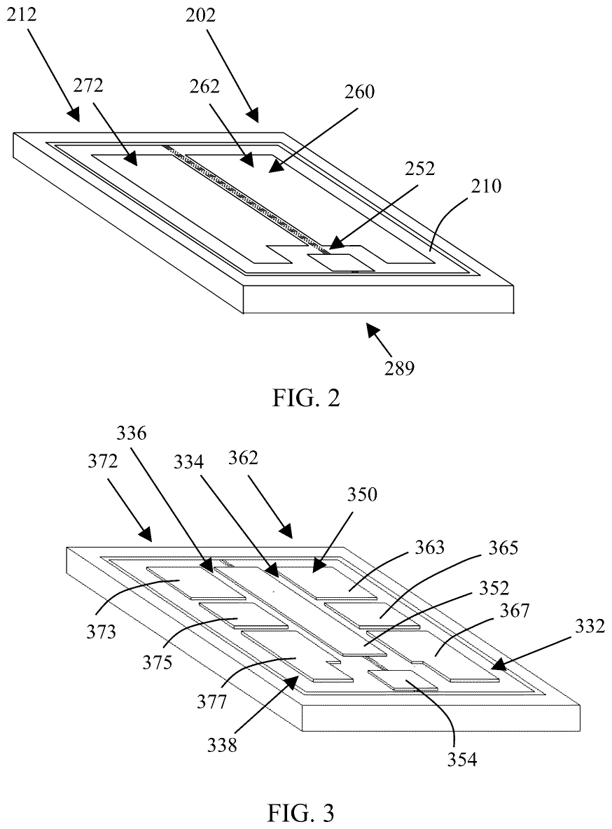

In FIGS. 1A and 1B, the FET 140 is attached to the lead frame 120. The FET 140 comprises a gate bus line 252 of FIG. 2, a gate electrode 154, and a source electrode 260 of FIG. 2 on a top surface of the FET 140 and a drain electrode 289 of FIG. 2 on a bottom surface of the FET 140. The gate bus line 252 of FIG. 2 directly connects to the gate electrode 154.

In FIG. 2, the source electrode 260 comprises a first source pad 262 on a first side 202 of the gate bus line 252; and a second source pad 272 on a second side 212 of the gate bus line 252 opposite the first side of the gate bus line 252. The first source pad 262, the second source pad 272 and the gate electrode 154 are exposed from opening windows of a top passivation layer 210. The gate bus line 252 is covered by the passivation layer 210.

In examples of the present disclosure, the copper layer 350 of FIG. 3 comprises first two or more copper sections 362 attached to a top surface of the first source pad 262, second two or more copper sections 372 attached to a top surface of the second source pad 272, a gate copper section 354 attached to a top surface of the gate electrode 154, and a bus copper section 352 extends from a first source pad area adjacent to the gate bus line to a second source pad area adjacent to the gate bus line. The bus copper section 352 covers a pre-determined portion of the gate bus line 252 along the length of the gate bus line 252. The bus copper section 352 is insulted from the gate bus line 252 by the passivation layer 210 overlaying the gate bus line. The bus copper section 352 attached to a top surface of the first source pad 262 on the first side of the gate bus line 252 and attached to a top surface of the second source pad 272 on the second side of the gate bus line 252. In one example, the pre-determined portion is in a range from 50% to 95% of length of the gate bus line 252. In another example, the pre-determined portion is in a range from 70% to 90% of length of the gate bus line 252. In examples of the present disclosure, copper layer 350 of FIG. 3 is formed by an electro plating process. Though three copper sections (copper section 363, copper section 365, and copper section 367) of the two or more copper sections 362 are shown in FIG. 3, the number of copper sections may vary. Though three copper sections (copper section 373, copper section 375, and copper section 377) of the two or more copper sections 372 are shown in FIG. 3, the number of copper sections may vary. Each copper section is separated from adjacent copper sections. Small, separated copper sections reduce the warpage of the FET after the plating process. It also reduces the warpage of the semiconductor package after the die bonding process.

The size and the thickness of the copper layer 350 of FIG. 3 may vary. The size and the thickness of the copper layer 350 of FIG. 3 may be adjusted so as to compensate the resistance of the different clip contact areas for different die sizes using a same clip size.

In examples of the present disclosure, the source metal clip 170 connects the source electrode 260 to the lead frame 120. The molding encapsulation 190 encloses the FET 140, the copper layer 350, the source metal clip 170, and a majority portion of the lead frame 120. In one example, a majority portion refers to larger than 50%.

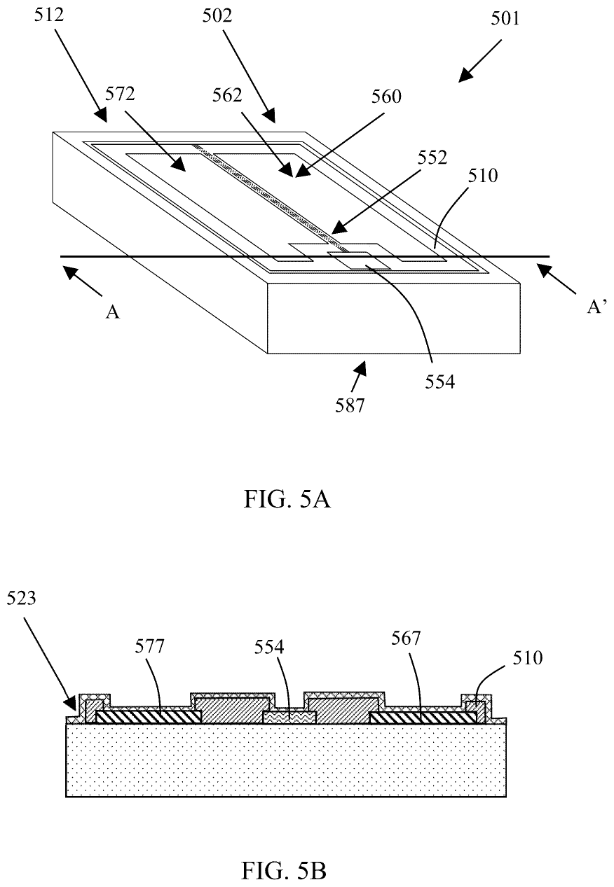

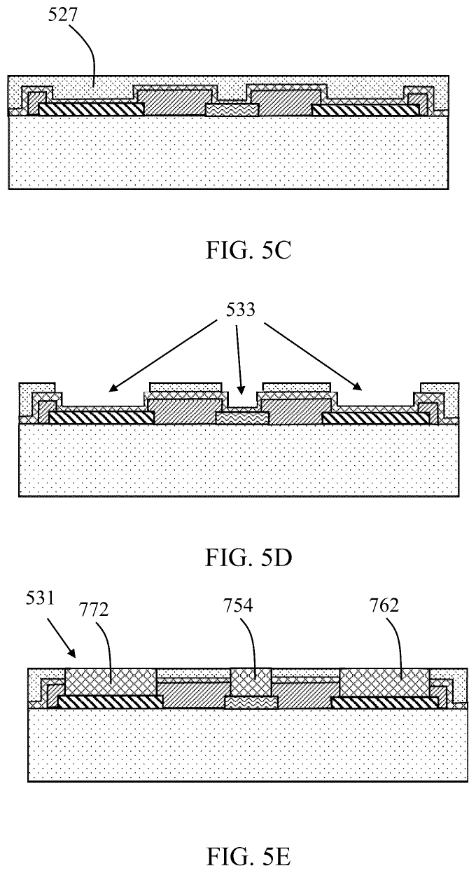

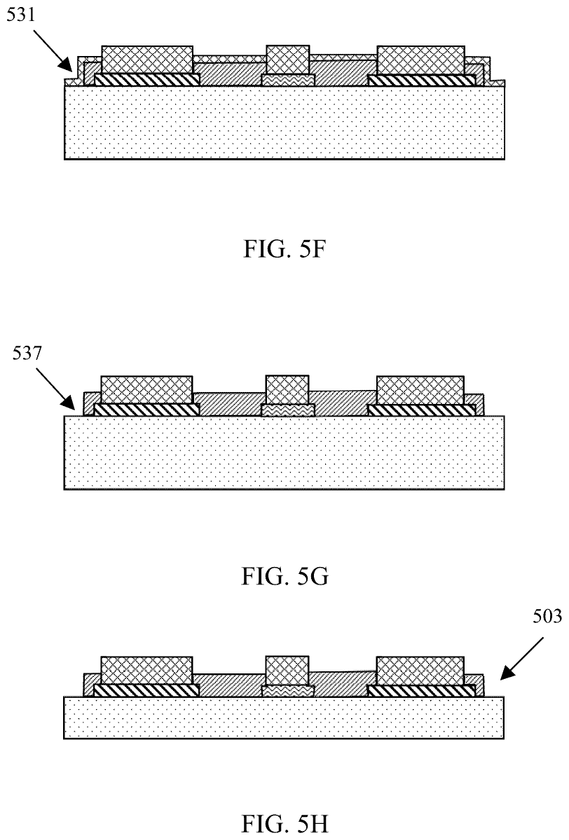

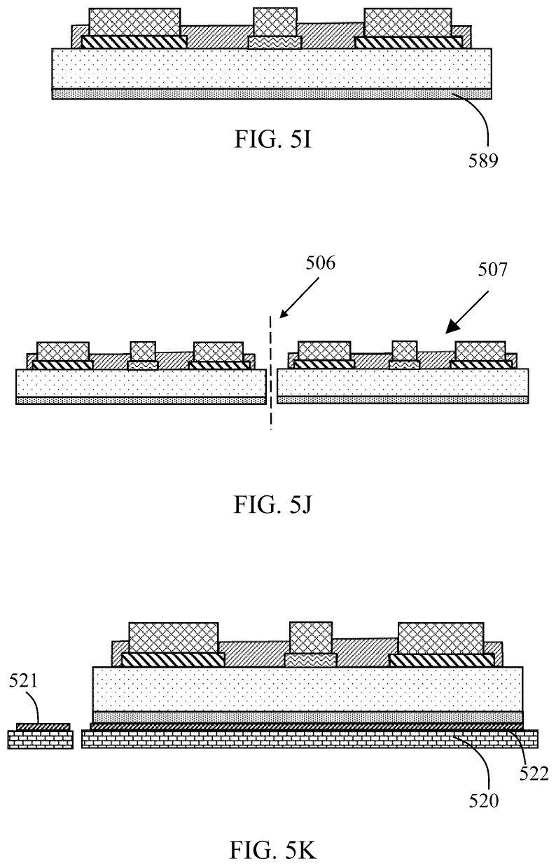

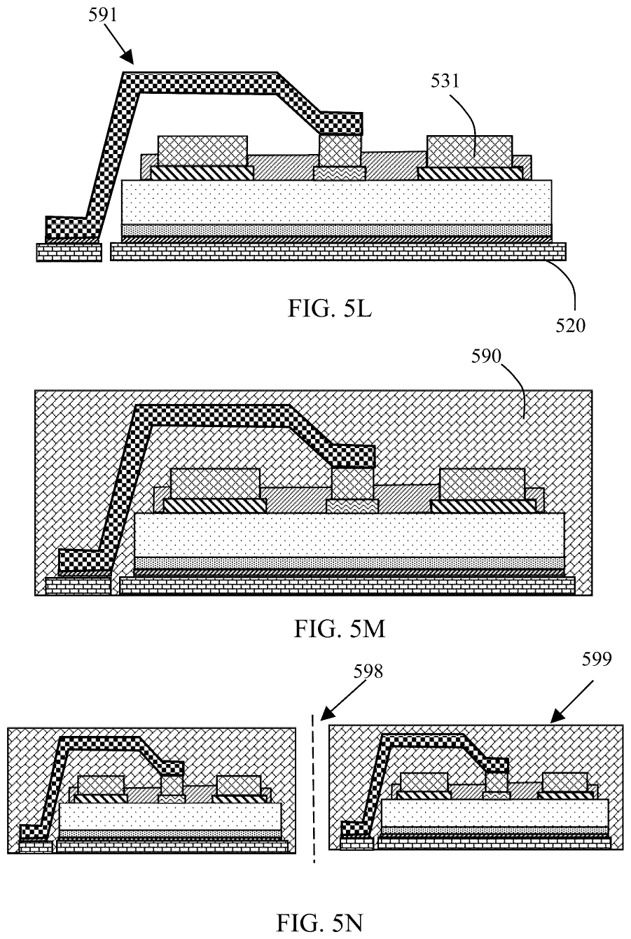

In examples of the present disclosure, the semiconductor package 100 further comprises a metallization layer 589 of FIG. 5I between the FET 140 and the lead frame 120.

In one example, the semiconductor package 100 further comprises a gate metal clip 181 connecting the gate electrode 154 to the lead frame 120. The molding encapsulation 190 further encloses the gate metal clip 181. In another example, the semiconductor package 102 further comprises a bond wire 183 connecting the gate electrode 154 to the lead frame 120. The molding encapsulation further encloses the bond wire 183.

The first source pad 262, the second source pad 272, and the gate electrode 154 are not covered by Nickel-Gold (NiAu) or Nickel-Palladium-Gold (NiPdAu). In one example of this invention, the first source pad 262, the second source pad 272, the gate electrode 154 and the gate bus line 252 comprise Aluminum layer less than 4 μm and preferably with 0.5-2.5 um thickness.

An area of a respective top surface of each of the two or more copper sections 362 is in a range from 5% to 25% of an area of a top surface of the semiconductor package 100. An area of a respective top surface of each of the two or more copper sections 372 is in the range from 5% to 25% of the area of the top surface of the semiconductor package 100.

In examples of the present disclosure, to facilitate compactness, first side surfaces 332 of the two or more copper sections 362 are co-planar. Second side surfaces 334 of the two or more copper sections 362 are co-planar. The second side surfaces 334 of the two or more copper sections 362 opposite the first side surfaces 332 of the two or more copper sections 362. First side surfaces 336 of the two or more copper sections 372 are co-planar. Second side surfaces 338 of the two or more copper sections 372 are co-planar. The second side surfaces 338 of the two or more copper sections 372 opposite the first side surfaces 336 of the two or more copper sections 372. A top-side surface of a first selective one (copper section 363) of the two or more copper sections 362 and a top-side surface of a first selective one (copper section 373) of the two or more copper sections 372 are co-planar. A bottom-side surface of a second selective one (copper section 367) of the two or more copper sections 362 and a bottom-side surface of a second selective one (copper section 377) of the two or more copper sections 372 are co-planar.

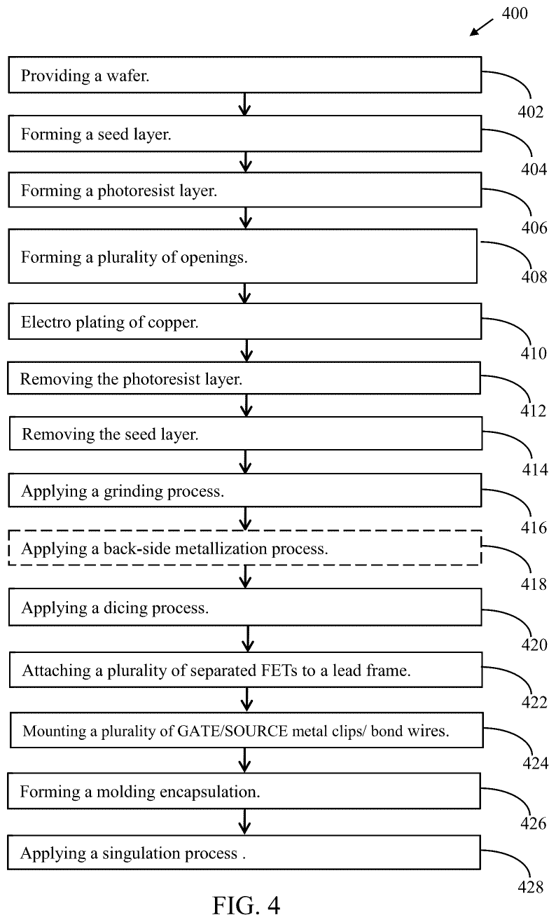

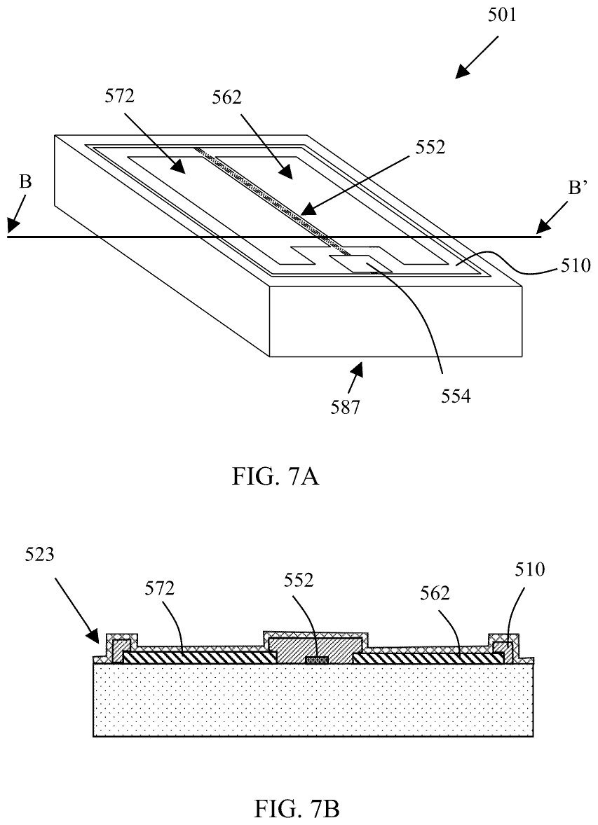

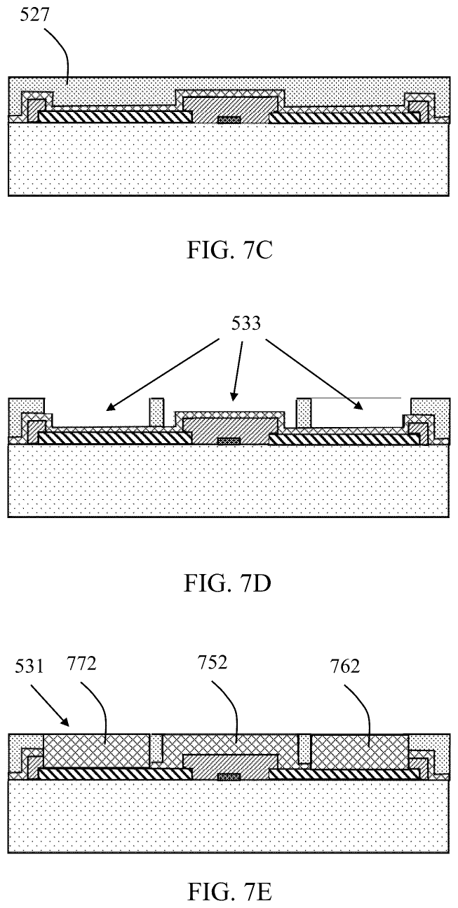

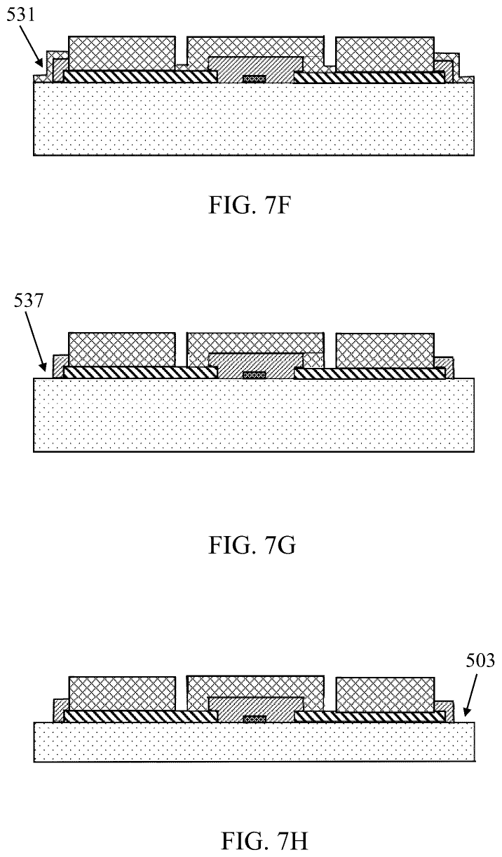

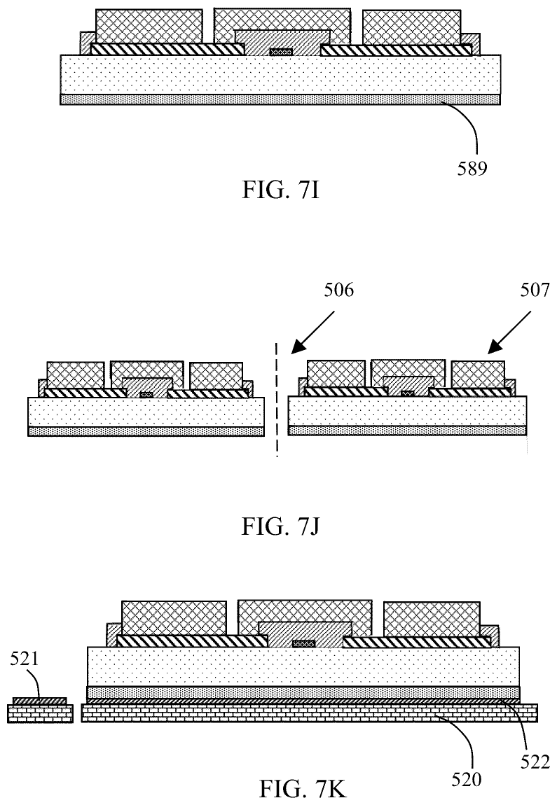

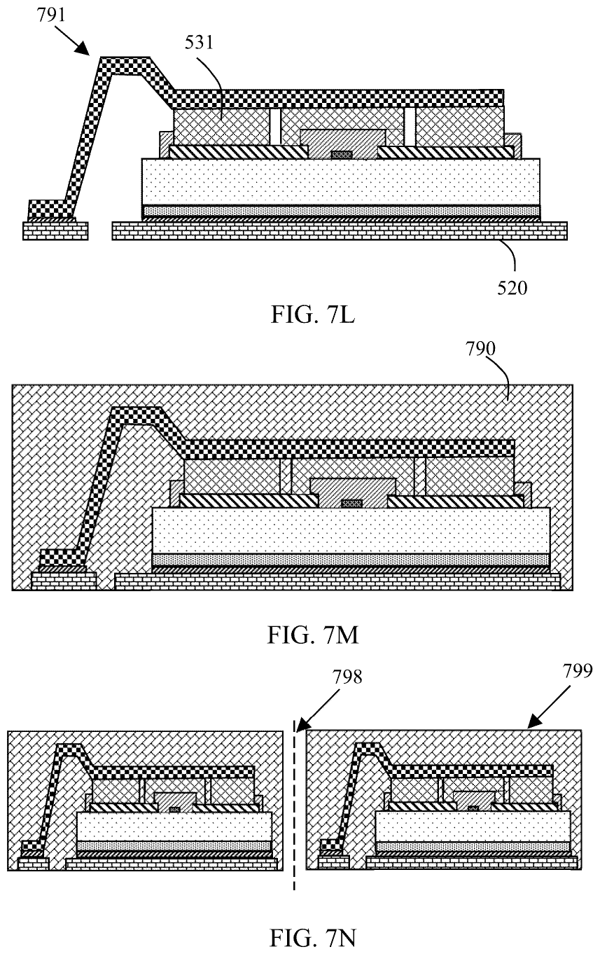

FIG. 4 is a flowchart of a process 400 to develop a plurality of semiconductor packages in examples of the present disclosure. FIGS. 5A, 5B, 5C, 5D, 5E, 5F, 5G, 5H, 5I, 5J, 5K, 5L, 5M, and 5N show the cross sections of the corresponding steps of the process 400 of FIG. 4 in examples of the present disclosure. FIG. 5A shows a perspective view and FIGS. 5B, 5C, 5D, 5E, 5F, 5G, 5H, 5I, 5J, 5K, 5L, 5M, and 5N show the cross sections, viewed from a direction perpendicular to the AA′ plane of FIG. 5A. FIGS. 7A, 7B, 7C, 7D, 7E, 7F, 7G, 7H, 7I, 7J, 7K, 7L, 7M, and 7N show other cross sections of the corresponding steps of the process 400 of FIG. 4 in examples of the present disclosure. FIG. 7A shows a perspective view and FIGS. 7B, 7C, 7D, 7E, 7F, 7G, 7H, 7I, 7J, 7K, 7L, 7M, and 7N show the cross sections, viewed from a direction perpendicular to the BB′ plane of FIG. 7A. The process 400 may start from block 402.

For simplicity, only a single FET is shown in FIGS. 5A, 5B, 5C, 5D, 5E, 5F, 5G, 5H, 5I, 5K, 5L, and 5M and only two FETs are shown in FIGS. 5J and 5N. For simplicity, only a single FET is shown in FIGS. 7A, 7B, 7C, 7D, 7E, 7F, 7G, 7H, 7I, 7K, 7L, and 7M and only two FETs are shown in FIGS. 7J and 7N.

In block 402, referring now to FIG. 5A and FIG. 7A, a wafer is provided. The wafer comprises a plurality of FETs (only a single FET 501 is shown in FIG. 5A). The FET 501 comprises a gate bus line 552, a gate electrode 554, and a source electrode 560 on a top surface of the FET 501 and a drain electrode 587 on a bottom surface of the FET 501. The gate bus line 552 directly connects to the gate electrode 554.

The source electrode 560 comprises a first source pad 562 on a first side 502 of the gate bus line 552; and a second source pad 572 on a second side 512 of the gate bus line 552 opposite the first side of the gate bus line 552. The first source pad 562, the second source pad 572 and the gate electrode 554 are exposed from windows of a top passivation layer 510. The gate bus line 552 is covered by the passivation layer 510.

In block 404, referring now to FIG. 5B and FIG. 7B, a seed layer 523 is formed. The seed layer 523 covers substantially the entire wafer. Block 404 may be followed by block 406.

In block 406, referring now to FIG. 5C and FIG. 7C, a photoresist layer 527 is formed. Block 406 may be followed by block 408.

In block 408, referring now to FIG. 5D and FIG. 7D, a plurality of openings 533 are formed (by masking process to expose the plurality of openings 533) in places where copper is intended to be plated. Block 408 may be followed by block 410.

In block 410, referring now to FIG. 5E and FIG. 7E, a copper layer 531 is formed by an electro plating process. The copper layer 531 comprises first two or more copper sections 762 attached to a top surface of the first source pad 562, second two or more copper sections 772 attached to a top surface of the second source pad 572, a gate copper section 754 attached to a top surface of the gate electrode 554, and a bus copper section 752 covers a pre-determined portion of the gate bus line 552 along the length of the gate bus line 552. In one example, the pre-determined portion is in a range from 50% to 95% of the length of gate bus line 552. In another example, the pre-determined portion is in a range from 70% to 90% of the length of gate bus line 552. The bus copper section 752 is insulted from the gate bus line 552 by the passivation layer 510 overlaying the gate bus line. In examples of this disclosure, the bus copper section 752 has a width extending from an area of the first source pad adjacent to the gate bus line to an area if the second source pad adjacent to the gate bus line. The bus copper section 752 may be wide enough to attach to a top surface of the first source pad 562 on the first side of the gate bus line 552 and to attach to a top surface of the second source pad 572 on the second side of the gate bus line 552.

Referring now to FIG. 3, though three cover sections (copper section 363, copper section 365, and copper section 367) of the first two or more copper sections 362 are shown, the number of copper sections may vary. Though three copper sections (copper section 373, copper section 375, and copper section 377) of the second two or more copper sections 372 are shown in FIG. 3, the number of copper sections may vary. Small, separated copper sections reduce the warpage of the FET after the plating process. It also reduces the warpage of the semiconductor package after the die bonding process.

Still referring to FIG. 3, in examples of the present disclosure, to facilitate compactness, first side surfaces 332 of the first two or more copper sections 362 are co-planar. Second side surfaces 334 of the first two or more copper sections 362 are co-planar. The second side surfaces 334 of the first two or more copper sections 362 opposite the first side surfaces 332 of the first two or more copper sections 362. First side surfaces 336 of the second two or more copper sections 372 are co-planar. Second side surfaces 338 of the second two or more copper sections 372 are co-planar. The second side surfaces 338 of the second two or more copper sections 372 opposite the first side surfaces 336 of the second two or more copper sections 372. A top-side surface of a first selective one (copper section 363) of the first two or more copper sections 362 and a top-side surface of a first selective one (copper section 373) of the second two or more copper sections 372 are co-planar. A bottom-side surface of a second selective one (copper section 367) of the first two or more copper sections 362 and a bottom-side surface of a second selective one (copper section 377) of the second two or more copper sections 372 are co-planar. Block 402 may be followed by block 404.

The size and the thickness of the copper layer 531 may vary. The size and the thickness of the copper layer 531 may be adjusted so as to compensate the resistance of the different clip contact areas for different die sizes using a same clip size. Block 410 may be followed by block 412.

In block 412, referring now to FIG. 5F and FIG. 7F, the photoresist layer 527 is removed so that side surfaces of the copper layer 531 are exposed. Block 412 may be followed by block 414.

In block 414, referring now to FIG. 5G and FIG. 7G, the seed layer 523 is removed so that portions of a top surface 537 of the FET 501 are exposed. Block 414 may be followed by block 416.

In block 416, referring now to FIG. 5H and FIG. 7H, a grinding process is applied so as to form a thinned FET 503. Block 416 may be followed by optional block 418.

In optional block 418 (shown in dashed lines), referring now to FIG. 5I and FIG. 7I, a back-side metallization process is applied so as to form a metallization layer 589. Optional block 418 may be followed by block 420.

In block 420, referring now to FIG. 5J and FIG. 7J, a dicing process, along the plurality of scribe lines 506, is applied so as to form a plurality of separated devices 507. Block 420 may be followed by block 422.

In block 422, referring now to FIG. 5K and FIG. 7K, the plurality of separated devices 507 are attached to a lead frame 520 including a clip paddle 521 and a die paddle 522. Block 422 may be followed by block 424.

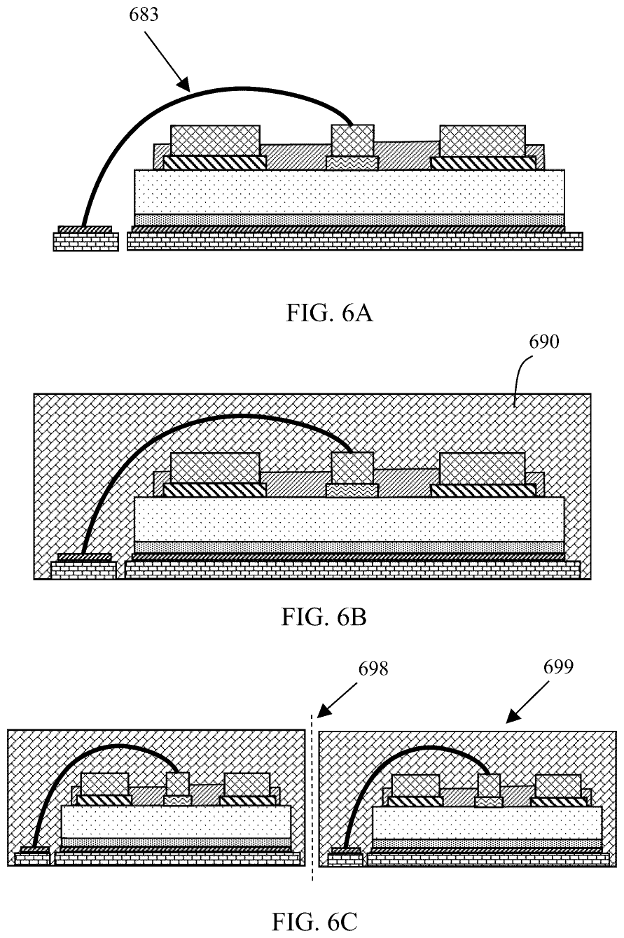

In block 424, referring now to FIG. 5L, FIG. 6A, and FIG. 7L, a plurality of source metal clips 791 of FIG. 7L, a plurality of gate clips 591 of FIG. 5L, or a bond wire 683 of FIG. 6A, are mounted. The plurality of source metal clips 791 of FIG. 7L, a plurality of gate clips 591 of FIG. 5L, or a bond wire 683 of FIG. 6A connect the copper layer 531 to the lead frame 520. Each source metal clip of the plurality of source metal clips 791 is attached to a respective one of the first two or more copper sections 362 of the copper layer 531 and a respective one of the second two or more copper sections 372 of the copper layer 531. Block 424 may be followed by block 426.

In block 426, referring now to FIG. 5M, FIG. 6B, and FIG. 7M, a molding encapsulation 590 of FIG. 5M, a molding encapsulation 690 of FIG. 6B, and a molding encapsulation 790 of FIG. 7M are formed. The molding encapsulation 590 encloses the plurality of separated devices 507, the copper layer 531, the plurality of source metal clips 791 of FIG. 7L, a plurality of gate clips 591 of FIG. 5L, or a bond wire 683 of FIG. 6A, and a majority portion of the lead frame 520. In one example, a majority portion refers to larger than 50%. Block 426 may be followed by block 428.

In block 428, referring now to FIG. 5N, FIG. 6C, and FIG. 7N, a singulation process is applied. In FIG. 5N, a singulation process along the plurality of scribe lines 598, is provided to cut through the connected semiconductor packages so as to form a plurality of semiconductor packages 599. In FIG. 6C, a singulation process along the plurality of scribe lines 698, is provided to cut through the connected semiconductor packages so as to form a plurality of semiconductor packages 699. In FIG. 7N, a singulation process along the plurality of scribe lines 798, is provided to cut through the connected semiconductor packages so as to form a plurality of semiconductor packages 799. In examples of the present disclosure, each of the plurality of semiconductor packages 599 of FIG. 5N, the plurality of semiconductor packages 699 of FIG. 6C, and the plurality of semiconductor packages 799 of FIG. 7N is a MOSFET.

Those of ordinary skill in the art may recognize that modifications of the embodiments disclosed herein are possible. For example, a total number of the source pads may vary. Other modifications may occur to those of ordinary skill in this art, and all such modifications are deemed to fall within the purview of the present invention, as defined by the claims.

1. A semiconductor package comprising:
a lead frame;
a field-effect transistor (FET) attached to the lead frame, the FET comprising:
a gate bus line, a gate electrode, and a source electrode on a top surface of the FET, the source electrode comprising:
a first source pad on a first side of the gate bus line; and
a second source pad on a second side of the gate bus line opposite the first side of the gate bus line; and
a drain electrode on a bottom surface of the FET;
a copper layer comprising:
first two or more copper sections attached to a top surface of the first source pad;
second two or more copper sections attached to a top surface of the second source pad; and
a bus copper section covering a pre-determined portion of the gate bus line;
a source metal clip electrically connecting the source electrode to a source lead of the lead frame; and
a molding encapsulation enclosing the FET, the copper layer, the source metal clip, and a majority portion of the lead frame.

2. The semiconductor package of claim 1 further comprising:
a gate copper section covering the gate electrode.

3. The semiconductor package of claim 2 further comprising:
a gate metal clip electrically connecting the gate electrode to a gate lead of the lead frame.

4. The semiconductor package of claim 1 further comprising:
a bond wire connecting the gate electrode to the lead frame.

5. The semiconductor package of claim 1, wherein the copper layer is formed by an electro plating process.

6. The semiconductor package of claim 1, wherein the first source pad, the second source pad, and the gate electrode are not covered by Nickel-Gold (NiAu) or Nickel-Palladium-Gold (NiPdAu).

7. The semiconductor package of claim 1, wherein an area of a respective top surface of each of the first two or more copper sections is in a range from five percent to twenty-five percent of an area of a top surface of the semiconductor package; and
wherein an area of a respective top surface of each of the second two or more copper sections is in the range from five percent to twenty-five percent of the area of the top surface of the semiconductor package.

8. The semiconductor package of claim 1, wherein the gate bus line directly connects to the gate electrode.

9. The semiconductor package of claim 8, wherein first side surfaces of the first two or more copper sections are co-planar;
wherein second side surfaces of the first two or more copper sections are co-planar;
wherein the second side surfaces of the first two or more copper sections opposite the first side surfaces of the first two or more copper sections;
wherein first side surfaces of the second two or more copper sections are co-planar;
wherein second side surfaces of the second two or more copper sections are co-planar;
wherein the second side surfaces of the second two or more copper sections opposite the first side surfaces of the second two or more copper sections;
wherein a top-side surface of a first selective one of the first two or more copper sections and a top-side surface of a first selective one of the second two or more copper sections are co-planar; and
wherein a bottom-side surface of a second selective one of the first two or more copper sections and a bottom-side surface of a second selective one of the first two or more copper sections are co-planar.

10. The semiconductor package of claim 1, wherein the semiconductor package is a metal oxide semiconductor field effect transistor (MOSFET).

11. A method for fabricating a plurality of semiconductor packages, the method comprising the steps of:
providing a wafer comprising
a plurality of field-effect transistors (FETs), each FET of the plurality of FETs comprising:
a respective gate bus line, a respective gate electrode, and a respective source electrode on a respective top surface of said each FET, the respective source electrode comprising:
a first source pad on a first side of the respective gate bus line; and
a second source pad on a second side of the respective gate bus line opposite the first side of the respective gate bus line; and
a respective drain electrode on a respective bottom surface of said each FET;
forming a seed layer;
forming a photoresist layer;
forming a plurality of patterned lines and a plurality of openings;
electro plating of copper comprising:
first two or more copper sections attached to a top surface of the first source pad;
second two or more copper sections attached to a top surface of the second source pad;
a gate copper section covering the respective gate electrode; and
a bus copper section covering a pre-determined portion of the respective gate bus line;
removing the photoresist layer;
removing the seed layer;
grinding a back side of the wafer so as to formed a thinned wafer;
applying a dicing process forming a plurality of separated FETs;
attaching the plurality of separated FETs to a lead frame;
mounting a respective source metal clip of a plurality of source metal clips connecting the respective source electrode of each of the plurality of separated FETs to the lead frame;
forming a molding encapsulation enclosing the plurality of separated FETs, the plated copper, the plurality of source metal clips, and a majority portion of the lead frame; and
applying a singulation process forming the plurality of semiconductor packages.

12. The method of claim 11 further comprising the step of:
after the step of mounting the respective source metal clip, mounting a respective gate metal clip of a plurality of gate metal clips connecting the respective gate electrode of each of the plurality of separated FETs to the lead frame.

13. The method of claim 11, further comprising the step of:
after the step of mounting the respective source metal clip, mounting a respective bond wire of a plurality of bond wires connecting the respective gate electrode of each of the plurality of separated FETs to the lead frame.

14. The method of claim 11, wherein the plated copper filled the plurality of openings.

15. The method of claim 11, wherein the first source pad, the second source pad, and the respective gate electrode are not covered by Nickel-Gold (NiAu) or Nickel-Palladium-Gold (NiPdAu).

16. The method of claim 11, wherein an area of a respective top surface of each of the first two or more copper sections is in a range from five percent to twenty-five percent of an area of a top surface of a respective semiconductor package of the plurality of semiconductor packages; and
wherein an area of a respective top surface of each of the second two or more copper sections is in the range from five percent to twenty-five percent of the area of the top surface of the respective semiconductor package of the plurality of semiconductor packages.

17. The method of claim 11, wherein the respective gate bus line directly connects to the respective gate electrode.

18. The method of claim 17, wherein first side surfaces of the first two or more copper sections are co-planar;
wherein second side surfaces of the first two or more copper sections are co-planar;
wherein the second side surfaces of the first two or more copper sections opposite the first side surfaces of the first two or more copper sections;
wherein first side surfaces of the second two or more copper sections are co-planar;
wherein second side surfaces of the second two or more copper sections are co-planar;
wherein the second side surfaces of the second two or more copper sections opposite the first side surfaces of the second two or more copper sections;
wherein a top-side surface of a first selective one of the first two or more copper sections and a top-side surface of a first selective one of the second two or more copper sections are co-planar; and
wherein a bottom-side surface of a second selective one of the first two or more copper sections and a bottom-side surface of a second selective one of the second two or more copper sections are co-planar.

19. The method of claim 11, wherein each semiconductor package of the plurality of semiconductor packages is a metal oxide semiconductor field effect transistor (MOSFET).
